(19) United States
(12) Patent Application Publication
(10) Pub. No.: US 2012/0190166 A1
(43) Pub. Date: Jul. 26, 2012

(54) METHOD FOR MANUFACTURING SEMICONDUCTOR DEVICE AND METHOD FOR FORMING HARD MASK

(75) Inventor: Kazuhiro OKUDA, Tokyo (JP)

(73) Assignee: ELPIDA MEMORY, INC., Tokyo (JP)

(21) Appl. No.: 13/354,593

(22) Filed: Jan. 20, 2012

(30) Foreign Application Priority Data
Jan. 20, 2011 (JP) 2011-009713

(51) Int. Cl. H01L 21/02; H01L 21/32

(52) U.S. Cl. 438/386; 438/761; 257/E21.008; 257/E21.258

(57) ABSTRACT

A method for manufacturing a semiconductor device comprises forming a base film on a semiconductor substrate, forming an amorphous carbon film on the base film, forming a pattern of the amorphous carbon film, and etching the base film using the amorphous carbon film as a mask. The film density of the amorphous carbon film is reduced from surface of the amorphous carbon film to face of the amorphous carbon film adjacent to the base film.

This application is based upon and claims the benefit of priority from Japanese Patent Application No. 2011-009713, filed on Jan. 20, 2011, the disclosure of which is incorporated herein in its entirety by reference.

### TECHNICAL FIELD

The present invention relates to method for manufacturing semiconductor device and method for forming hard mask.

### BACKGROUND ART

In manufacturing a semiconductor device, a photoresist is applied onto a processed film such as an interlayer insulating film, and a metal film, etc in a semiconductor substrate, and the processed film is etched using a resister mask patterned by photolithography. In order to increase integrate degree of semiconductor device, it is necessary to develop photolithography technology for miniaturizing a pattern such as wiring. To make an exposed light source become a short wavelength is effective for the miniaturization of pattern. Until now, as a short wavelength of an exposed light source, an i-ray (wavelength: 365 nm) of a high-pressure mercury lamp has been developed to a KrF laser (248 nm), and further to an ArF laser (193 nm).

By making an exposed light source become a short wavelength, the characteristics required for a photoresist have been changed. In order to improve dry etching resistance, benzene ring-based material has been used for the conventional photoresist.

However, recently, as an alternate method for improving dry etching resistance of a resister mask without a benzene ring, a use of “hard mask” is worked out. Such method comprises forming a mask film made of a material having high dry etching resistance and a photoresist in order on a processed film, transferring a photoresist pattern to the mask film, and dry-etching the processed film using the mask film as a mask. The mask film is referred to as “hard mask.” Silicon oxide film or silicon nitride film is used as a material of a hard mask, but if a processed film is made of the same material as a hard mask, it is not possible to process the hard mask due to low etching selectivity. In this case, an amorphous carbon film (hereinafter, is referred as “AC film”) is used as a material of a hard mask, but since both a photoresist and the AC film are carbon-based, there is no etching selectivity between the photoresist and AC film. Thus, it is general to interpose an intermediate mask such as a silicon oxide film between a photoresist and a hard mask which is an AC film.

JP2009-253245 A1 discloses a process for etching an insulating film by using an amorphous carbon layer as a hard mask. JP2007-059496 A1 discloses a process for patterning a base layer by using a hard mask made of an amorphous carbon layer as a mask.

### SUMMARY OF THE INVENTION

In one embodiment, there is provided a method for manufacturing a semiconductor device, comprising:

forming a base film on a semiconductor substrate;

forming an amorphous carbon film on the base film so that a face of the amorphous carbon film adjacent to the base film has a smaller film density than a film density of a surface of the amorphous carbon film;

forming a first pattern in the amorphous carbon film; and

etching the base film using the amorphous carbon film including the first pattern as a mask to form a second pattern in the base film.

In another embodiment, there is provided a method for forming a hard mask, comprising:

forming a hard mask comprising an amorphous carbon film on a base film so that a face of the amorphous carbon film adjacent to the base film has a smaller film density than a film density of a surface of the amorphous carbon film; and

forming a pattern of the hard mask.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 7 explain a method for manufacturing a semiconductor device according to the first exemplary embodiment.

FIG. 8 is a cross-sectional view showing the change of pattern shape formed on a hard mask and a base film, wherein FIG. 8A shows an actual pattern shape according to the convention method and FIG. 8B shows an ideal pattern shape.

FIG. 9 is a cross-sectional view showing the change of pattern shape formed on a hard mask and a base film, wherein FIG. 9A shows an actual pattern shape according to the convention method and FIG. 9B shows an ideal pattern shape.

FIG. 10 is a cross-sectional view of a hard mask formed by continuously increasing a high frequency power.

FIG. 11 is a cross-sectional view of a hard mask made of three types of amorphous carbon films having different film densities.

FIG. 12 shows a semiconductor device according to the second exemplary embodiment.

FIG. 13 is a graph showing the relationship between a high frequency power and an AC film density at the time of forming a hard mask.

FIG. 14 is a graph showing the relationship between a pressure in a chamber and an AC film density at the time of forming a hard mask.

FIG. 15 is a graph showing the relationship between an AC film density and a side etching amount (side etching rate) at the time of patterning a hard mask.

FIG. 16 is one timing chart showing the switch of a high frequency power at the time of forming a hard mask.

FIG. 17 is one timing chart showing the switch of a high frequency power at the time of forming hard masks 4C to 4E.

FIG. 18 is one timing chart showing the switch of a flow rate when two hard masks having different film densities are formed by changing a pressure in a chamber.

In the drawings, reference numerals have the following meanings: 1; semiconductor substrate, 2; interlayer insulating film, 3; base film, 4, 4A, 4B, 4C, 4D, 4E; hard mask, 4a, 4b, 4c; step height, 5; intermediate mask, 6; photoresist, 7; contact hole, 10; DRAM (Dynamic Random Access Memory), 11; semiconductor substrate, 12; STI (Shallow Trench Isolation), 13; active region, 14; gate insulating film, 15; gate electrode, 16, 24, 43; insulating film, 17, 25, 44; sidewall insulating film, 18, 18 a, 18 b; diffusion layer, 19; first interlayer insulating film, 20, 20a, 20b; first contact plug, 21; second interlayer insulating film, 22; second contact plug, 23; first wiring, 26; third interlayer insulating film, 27; third contact plug, 28; contact pad, 29; cover film, 30; fourth interlayer insulating film, 31; fifth interlayer insulating film, 32; first beam, 33; second beam, 34; lower electrode, 35; capacity film, 36; upper electrode, 37; capacitor, 38; sixth interlayer insulating film, 39; fourth contact plug, 40; second wiring, 41; fifth contact plug, 42; third wiring, 45; sixth contact plug

### DESCRIPTION OF PREFERRED ILLUSTRATIVE EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

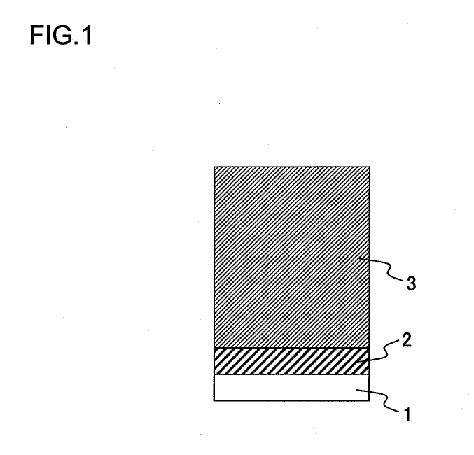

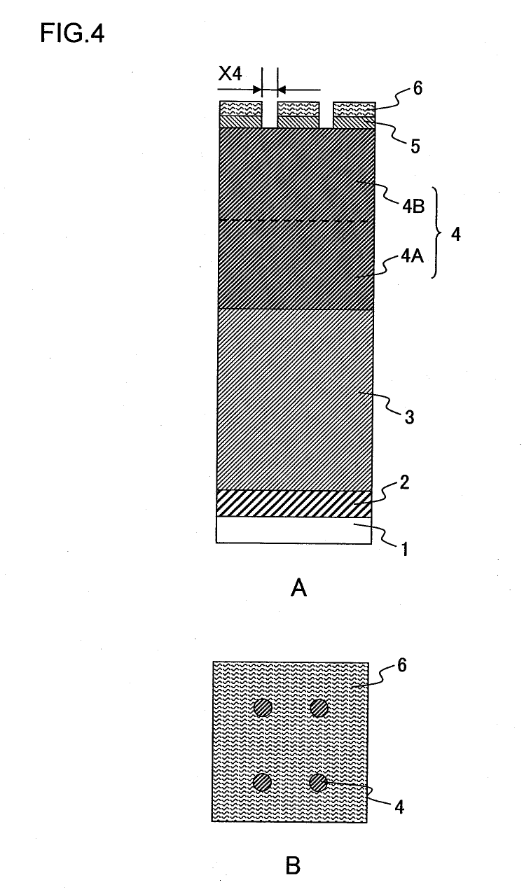

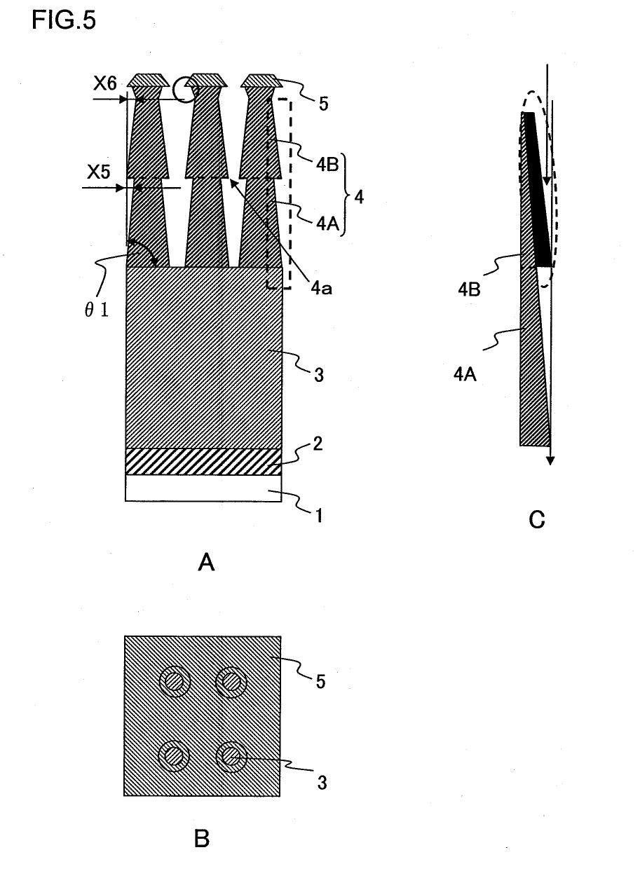

The preferred embodiments of the present invention will be in detail explained with reference to the annexed drawings. FIGS. 4A, 5A, 6A and 7A are cross-sectional views and FIGS. 4B, 5B, 6B and 7B are top views of FIGS. 4A, 5A, 6A and 7A, respectively. FIG. 5C is an enlarged view of the broken lined portion in FIG. 5A. FIGS. 1 to 3 and 8 to 12 are cross-sectional views.

### First Exemplary Embodiment

As shown in FIG. 1, an interlayer insulating film 2 made of a silicon oxide (SiO₂) film is formed by CVD (Chemical Vapor Deposition) so as to cover a semiconductor substrate 1 (hereinafter, referred to as “silicon substrate 1”) in which a transistor (not shown) is formed. Subsequently, a base film 3 made of a silicon oxide film is formed by CVD so as to cover the interlayer insulating film 2.

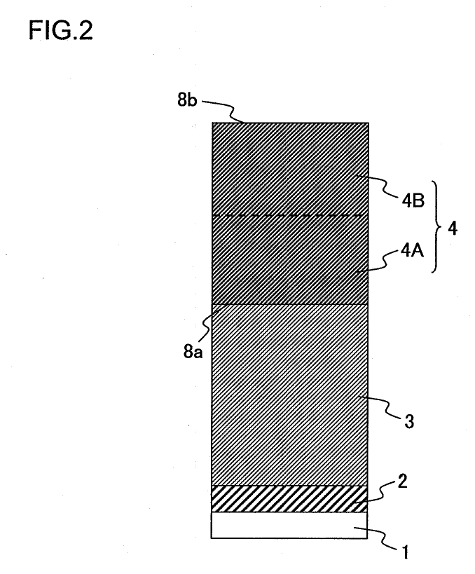

Subsequently, as shown in FIG. 2, a hard mask 4 made of an AC film having a thickness of 700 nm is formed by plasma CVD so as to cover the base film 3 (first step). Such plasma CVD uses high frequency plasma generated by applying a high frequency power to process gas while the pressure equal to or less than an atmospheric pressure is maintained in a reaction chamber into which the process gas is introduced. The thickness of the hard mask 4 is not limited to 700 nm, and may be equal to or more than 700 nm. In such plasma CVD, the process gas to be a material of a film forming is supplied to region between upper and lower electrodes, using a parallel and flat type film forming apparatus and a high frequency power is then applied to the upper electrode. The process gas is converted into plasma by a discharge between the electrodes resulting from the high frequency power, to form a hard mask on a semiconductor film heated on a heater between the electrodes.

In the process shown in FIG. 2, the hard mask 4 is formed so as to have different film densities in upper portion and lower portion thereof and includes two AC films having different film densities with each other. In other words, a lower hard mask 4A having a film density of 1.25 g/cm³ and a upper hard mask 4B having a film density of 1.38 g/cm³ are formed under different film forming conditions. First, the hard mask 4A is formed by providing propylene (C₃H₆) as process gas into a chamber (reaction chamber) in a flow rate of 600 sccm (standard cubic centimeter per minute) under a pressure in chamber of 5 Torr, at a heater temperature of 300° C., and a high frequency power of 300 watt (W). Subsequently, the hard mask 4B is formed by providing propylene into a chamber (reaction chamber) in a flow rate of 600 sccm, under a pressure in chamber of 5 Torr, at a heater temperature of 300° C. and a high frequency power of 750 W. Herein, helium (He) and argon (Ar) are supplied in chamber as carrier gas in 400 sccm and 8000 sccm, respectively. The film density of the hard mask 4A is not limited to 1.25 g/cm³, and may be between 1.2 g/cm³ and 2.0 g/cm³. Herein, in order to set the film density more than 2.0 g/cm³, a high frequency power of 2000 W or more is needed. However, since 2000 W exceeds the acceptable value of the film forming apparatus, it is actually impossible to do so. Also, the film density of 1.2 g/cm³ is almost the physical limit, and even if a high frequency power is further reduced, it is not possible to set the film density to be smaller than 1.2 g/cm³.

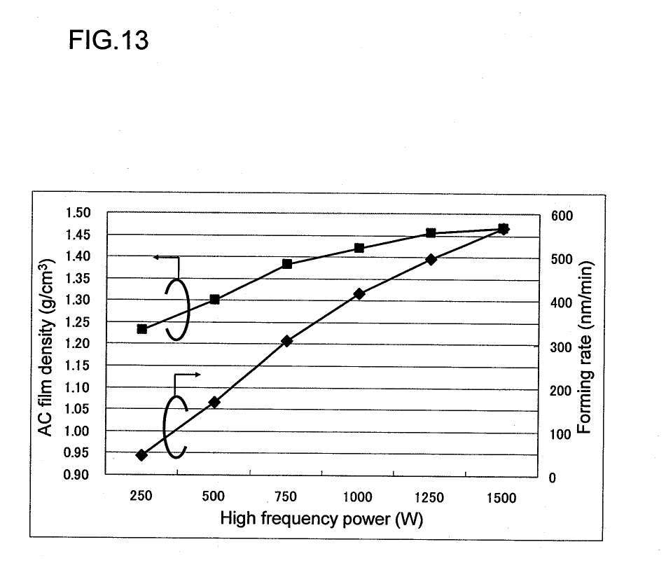

Therefore, it is possible to change the film densities of the hard masks 4A and 4B made of AC films, respectively in the same process by changing a high frequency power. FIG. 13 shows the relationship between a high frequency power and an AC film density. FIG. 13 plots each AC film density to each high frequency power (▪ mark) and each film forming rate to each high frequency power (♦ mark). As shown in FIG. 13, an AC film density is proportional to a high frequency power and a film density can be controlled by controlling a high frequency power. This is because as a high frequency power increases, the conversion of process gas into plasma is promoted and the generated plasma amount is increased, thereby obtaining a dense AC film having large film density. Also, a film forming rate is proportional to a high frequency power. This is because as a high frequency power increases, the conversion of process gas into plasma is promoted and the process gas that contributes to a film forming increases, thereby increasing a film forming rate.

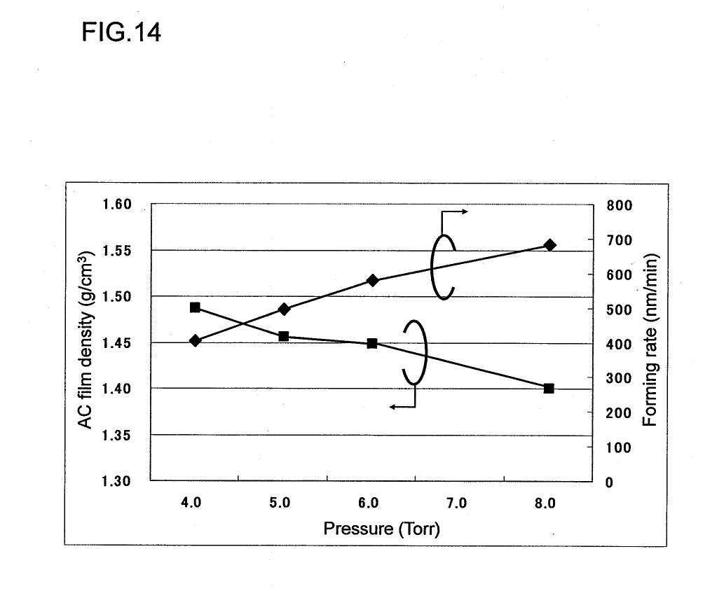

An AC film density may be changed by changing a pressure in a chamber. FIG. 14 shows the relationship between a pressure in a chamber and an AC film density. FIG. 14 plots each AC film density to each pressure in a chamber (▪ mark) and each film forming rate to each pressure in a chamber (▴ mark). As shown in FIG. 14, an AC film density is inversely proportional to a pressure in a chamber and a film density can be controlled by controlling a pressure in a chamber. This is because a pressure in a chamber reduces the conversion efficiency to plasma is improved and proportion of the process gas that contributes to a film forming increases, thereby obtaining an AC film having a large film density. Therefore, it is also possible to obtain an AC film having a large film density by maintaining a constant pressure in a chamber and reducing the flow rate of the process gas so that the partial pressure of the process gas reduces. Also, a film forming rate is proportional to a pressure in a chamber. This is because as a pressure in a chamber increases, the partial pressure of the process gas increases and the number of molecules of the process gas per unit volume increases, thereby increasing a film forming rate.

In this exemplary embodiment, the hard mask 4 has two different film densities, but the hard mask 4 is not limited to such hard mask. The film density of the face of the hard mask 4 adjacent to a base film may be smaller than the film density of the surface of the hard mask 4. Herein, the surface of the hard mask 4 is opposite to the face of the hard mask 4 adjacent to the base film and is the farthest from the base film. The hard mask 4 may have three or more different film densities. If the hard mask 4 is configured to have a plurality of different film densities, it is preferable to reduce the film density from its surface to the face adjacent to a base film gradually. In this case, among the different film densities of the hard mask 4, M₁/M₂ is preferably 1.1 to 2.0, wherein the film density M₁ is a film density of a portion having a large film density (a portion close to the surface) and the film density M₂ is a film density of a portion having a small film density (a portion close to the base film). If the ratio of the film density, M₁/M₂ falls within said range, the side etching of the hard mask reduces, and thus, a sidewall of an opening in the hard mask may be patterned so as to be more vertical.

Also, the high frequency power is not limited to 300 W or 750 W, the flow rate of propylene is not limited to 600 sccm, and the pressure in chamber is not limited to 5 Torr. For example, the hard mask 4 may be formed under conditions of a temperature 30 to 600° C., a high frequency power of 100 to 2000 W, a flow rate of process gas between 100 and 3000 sccm, and a pressure in chamber of 0.01 to 20 Torr.

The hard mask can obtain a desired film density by adjusting such conditions. As mentioned above, it is possible to increase a film density by increasing a temperature or a high frequency power or by reducing a flow rate of process gas or a pressure. In this exemplary embodiment, propylene is used as process gas, but the process gas is not limited to propylene and the other hydrocarbon gas may be used.

The film density of the hard mask may be measured by X-ray reflection (XRR). Such XXR uses the total reflection of an X-ray entered at a very low angle to a thin film (single film, or multilayer film) on a substrate and can nondestructively measure the film density and thickness of the thin film and interface roughness by measuring the dependency of total reflection X-ray intensity to incidence X-ray intensity on incidence angle to the surface of the thin film. In other words, if an angle of an incidence X-ray is equal to or more than a total reflection critical angle, the X-ray penetrates into the thin film and is divided into transmissive wave and reflected wave at the surface of a sample or interface, and thus, the reflected wave interferes. Therefore, the interference signal of the reflected wave caused by change of an optical path difference with changing an incidence angle is analyzed, to measure the thickness of the thin film and interface roughness. Also, the film density of the thin film can be measured from the total reflection critical angle.

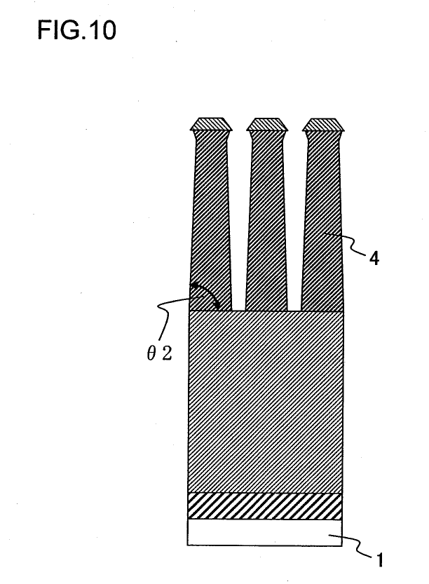

A switching a high frequency power and a pressure when forming a hard mask 4 will be in detail explained later with reference to FIGS. 15 to 17, and 10 and 11, respectively.

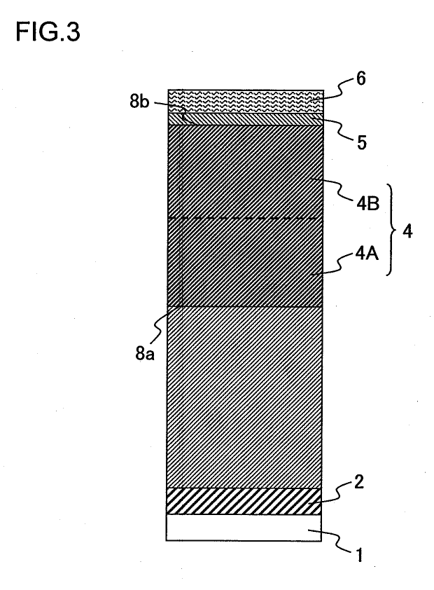

As shown in FIG. 3, an intermediate mask 5 made of a laminate film of a nitrogen-containing silicon oxide (SiON) film having a thickness of 55 nm and a silicon oxide film, is formed by CVD so as to cover the hard mask 4. Subsequently, a photoresist 6 having a thickness of 100 nm is formed so as to cover the intermediate mask 5. The hard mask 4 has a face 8a adjacent to the base film 3 and a surface 8b opposite to the face 8a.

Subsequently, as shown in FIG. 4, a pattern having a width X4 of 70 nm is formed in the intermediate mask 5 by photolithography and dry etching. At this time, the pattern of the intermediate mask 5 has a vertical shape and the intermediate mask 5 has substantially the same width as the X4 of the photoresist 6 from its top to bottom. Also, since dry etching can selectively etch a silicon oxide film, a dimension pattern formed in the intermediate mask 5 made of a silicon oxide film can be improved by thinning the photoresist 6.

Subsequently, as shown in FIG. 5, a first pattern is formed in the hard mask 4 by dry etching using the intermediate mask 5 as a mask (second step). The dry etching is performed using a parallel and flat plasma etching method under conditions of a pressure in a chamber of 20 mTorr, a temperature of 500° C., and a high frequency bias power of 500 W, and oxygen as process gas which is supplied into the chamber in a flow rate of 500 sccm.

Since dry etching can selectively etch carbon, it is possible to thin the intermediate mask 5 and to transfer an exact pattern of the intermediate mask 5 to the hard mask 4. An internal wall in an opening of the hard mask pattern formed by such dry etching is inclined. The angle θ1 of the hard mask 4 from the face flat parallel to the main surface of the silicon substrate is 85°. The θ1 is not limited to 85°. The θ1 may be 85° or more and the maximum θ1 is 90° which is an ideal angle. The internal wall in an opening of the hard mask pattern is inclined due to the aforementioned “side etching”. If the material comprised in the hard mask has the same characteristics, in the hard mask, the side etching amount of a portion positioned at higher height becomes larger.

However, in this step of this exemplary embodiment, the dry etching is subjected to the hard mask 4 having different film densities in its upper portion and lower portion under the same conditions. Therefore, step 4 is formed, depending on the film density of the hard mask 4. This is because that the hard mask 4 comprises a hard mask 4A having an AC film density of 1.25 g/cm³ and a hard mask 4B having a, AC film density of 1.38 g/cm³ and the hard masks 4A and 4B have different side etching amounts with each other.

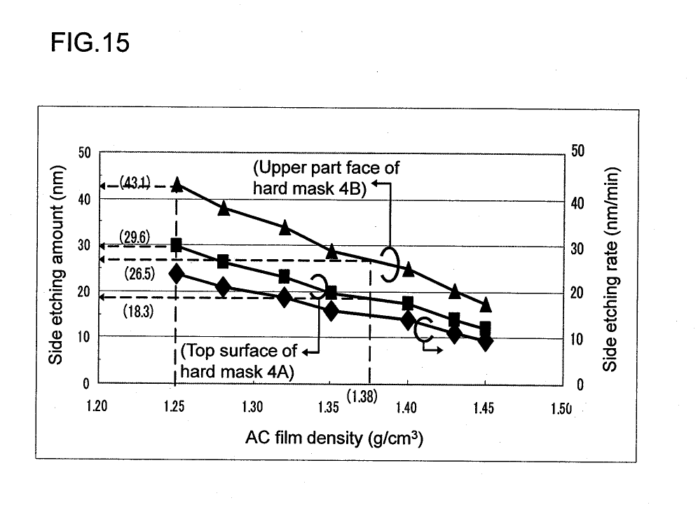

FIG. 15 shows the relationship between an AC film density and a side etching amount (side etching rate). FIG. 15 shows a side etching amount (▪ mark) for 75 seconds which is an etching time from the top face of the hard mask 4A to the top face of the base film 3 and a side etching amount (A mark) for 109 seconds which is an etching time from the upper part face of the hard mask 4B to the top face of the base film 3. The upper part face of the hard mask 4B is positioned at 200 nm below the top face of the hard mask 4B, and is etched at the maximum side etching amount (X6). The side etching amounts (▪ mark, ▴ mark) are calculated and plotted based on a side etching rate (♦ mark) found for each AC film density. As shown in FIG. 15, the side etching amount at the top face of the hard mask 4A is 29.6 nm, while the side etching amount at the bottom face of the hard mask 4B adjacent to the top face of the hard mask 4A is 18.3 nm. Therefore, a difference X5 between side etching amounts of the hard masks 4A and 4B is about 11 nm, and the hard mask 4B protrudes. Also, the maximum side etching amount X6 of the hard mask 4B is 26.5 nm which is smaller than the maximum side etching amount of 43.1 nm by 16 nm when the hard mask 4 is made of only the hard mask 4A.

As mentioned above, in the hard mask 4 of this exemplary embodiment, the end of the hard mask 4B which is the upper portion, protrudes from the end of the hard mask 4A which is the lower portion. In FIG. 5, the pattern in a circle in the upper portion of the hard mask 4 is inversely inclined when compared to the other portions, because, as mentioned above, etching product resulting from the overhang-shaped protruding intermediate mask 5 is adhered to the hard mask 4A and become a temporary protection film of the side etching.

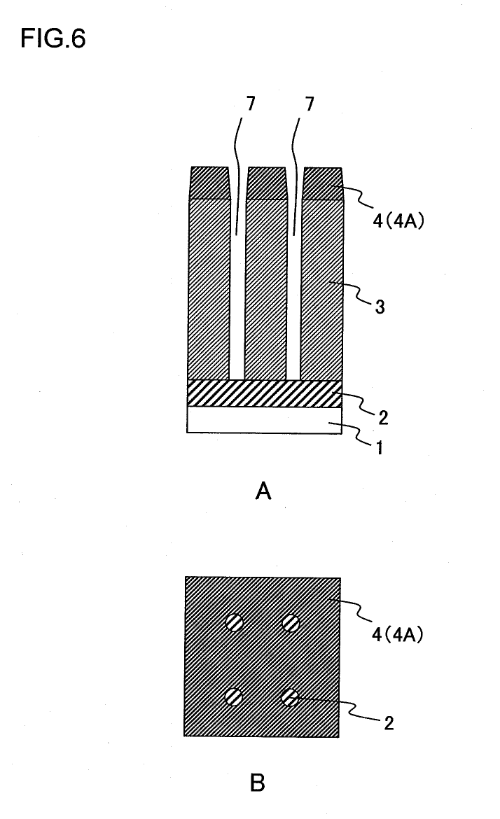

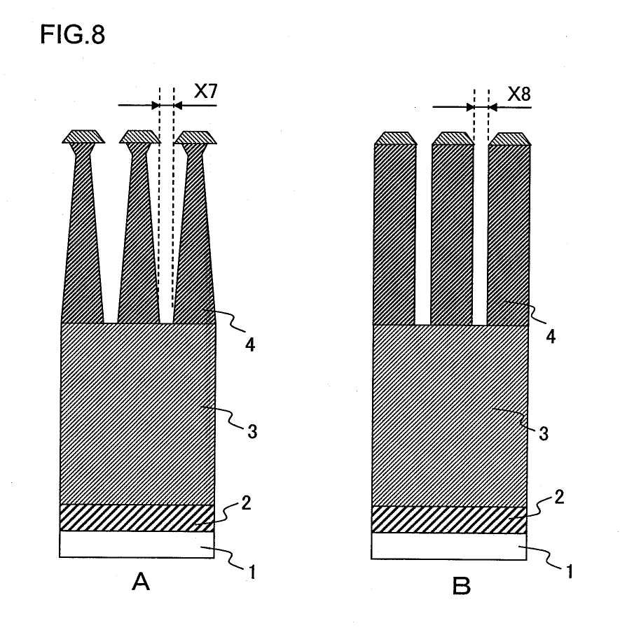

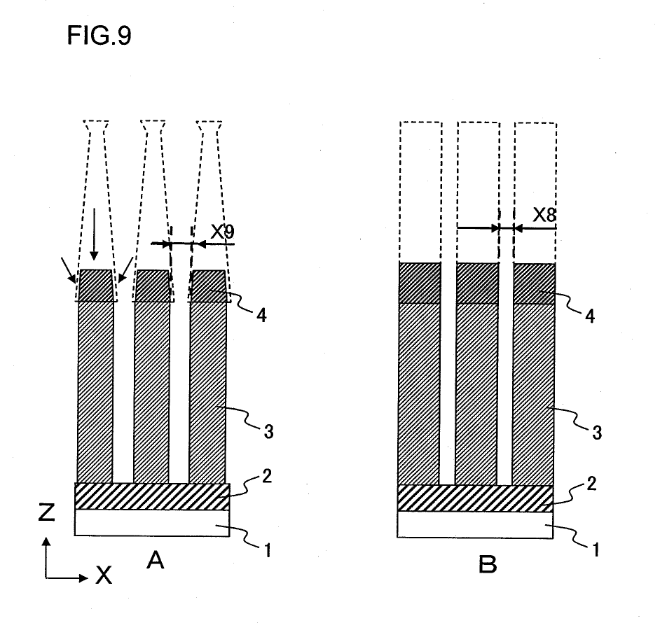

Subsequently, as shown in FIG. 6, a contact hole 7 is formed in the base film 3 as a second pattern by anisotropic dry etching using the hard mask 4 as a mask (third step). Herein, as shown in FIG. 5C enlarging the broken lined portion of FIG. 5A, the hard mask 4B prevents the hard mask 4A from being etched so as to prevent the diameter of the contact hole from increasing by the increase of the opening width of the hard mask 4A. Since in such dry etching, a silicon oxide film is etched, the intermediate mask 5 is entirely removed during the etching. Also, the entire of the hard mask 4B and a part of the hard mask 4A are removed and a part of the hard mask 4A remains. The shape of the contact hole 7 formed by such etching will be in detail provided later with reference to FIGS. 8 and 9.

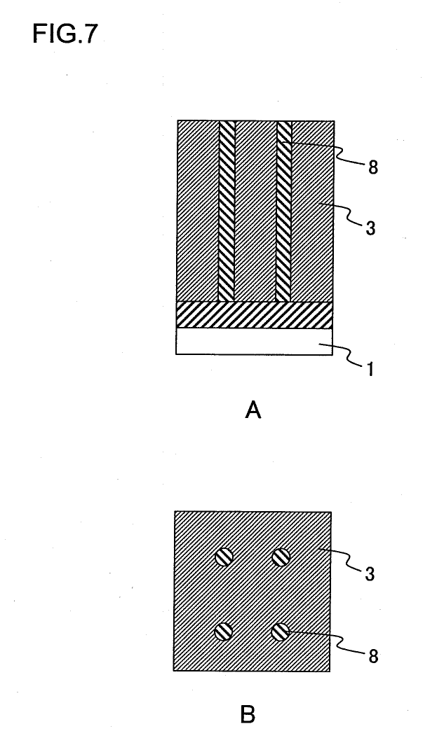

Subsequently, as shown in FIG. 7, the remaining hard mask 4 (4A) is removed by etching (fourth step). Thereafter, the base film is covered with conductive materials such as tungsten (W) so as to fill up the contact hole 7 formed in the base film 3 (fifth step). Subsequently, surplus conductive material on the top face of the base film 3 is removed by CMP (Chemical Mechanical Polishing) to complete a contact plug 8.

FIGS. 8 and 9 are cross-sectional views showing the change in pattern shape formed on the hard mask 4 and base film 3, FIGS. 8A and 9A show an actual pattern shape according to the conventional method and FIGS. 8B and 9B show an ideal pattern shape.

As shown in FIG. 8A, a pattern formed on the hard mask 4 is inclined as mentioned above and has a width X7 in the lower portion, and as shown in FIG. 8B, a pattern formed on the hard mask 4 is vertical and has a width X8.

Subsequently, as shown in FIG. 9A, if anisotropic dry-etching is performed to the base film 3 by using the hard mask 4 in FIG. 8 as a mask, in FIG. 9A, as the etching is performed, the width X9 of the pattern formed on the base film 3 becomes larger than the width X7 of the hard mask 4. Since the pattern of the hard mask 4 is inclined, the hard mask 4 is etched when the etching the base film 3. Therefore, since the location in the X direction in the pattern of the hard mask 4 moves backward, such malfunction of the mask is caused.

On the other hand, in FIG. 9B, even though the etching of the base film 3 is performed, the width X8 of the pattern does not increase. In other words, since the pattern of the hard mask 4 is vertical, even though the hard mask is etching, only its height lowers and the location of the pattern in the X direction does not move. Therefore, the width X8 does not change. In this way, the hard mask 4 is required to have function to maintain the dimension of the bottom portion of the pattern when etching is performed. Mask with the pattern which is closer to verticality, has excellent mask function.

Accordingly, in the hard mask 4 according to this exemplary embodiment shown in FIG. 5C, since the hard mask 4B having a large film density includes a broken lined portion in black, it remains more than the conventional hard mask 4 and is nearly vertical, thereby improving its function as a mask.

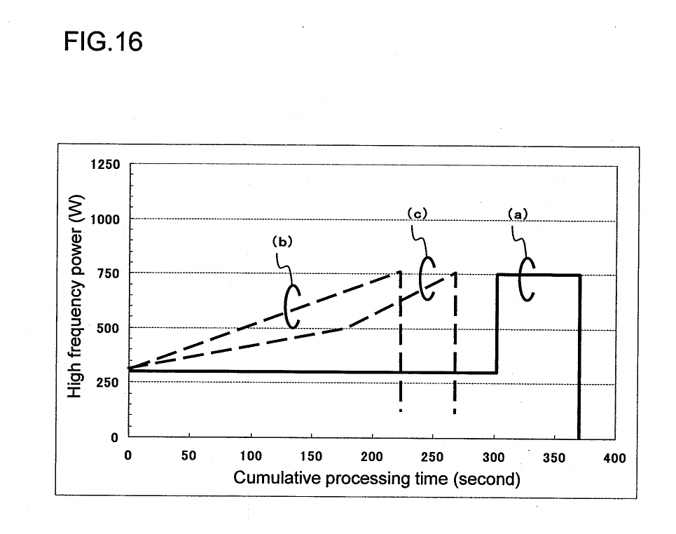

FIG. 16 is one timing chart showing the switch of high frequency power at the time of forming the hard mask 4 shown in FIG. 2, and each of the hard masks 4A and 4B has a thickness of 350 nm. As shown by reference character (a) in FIG. 16, in order to form the hard mask 4, first, the hard mask 4A to be the lower portion is formed by a high frequency power of 300 W. Subsequently, after 302 seconds from finishing forming the hard mask 4A, a high frequency power is increased up to 750 W in a step shape to form the hard mask 4B to be the upper portion, and then, after 307 seconds, the high frequency power is changed down to 0 W and the process for forming the hard mask 4A is finished.

Herein, a method for applying the high frequency power is not limited to a method which increases it in a step shape, and it may continuously increase from 0 to 223 seconds in a rate of 121 W/min, as shown by reference character (b) in FIG. 16. FIG. 10 shows the hard mask 4 formed by continuously increasing a high frequency power. As shown in FIG. 10, the high frequency power is continuously increased to reduce a step generated in hard mask 4 which has different film densities. As a result, the inclination angle θ2 of the pattern becomes more vertical than the inclination angle θ1 in FIG. 5, thereby improving its function as a mask. It is also possible to shorten a cumulative processing time by continuously increasing a high frequency power. This is because as shown in FIG. 13, a film forming rate is proportional to a high frequency power, and a continuous increase of a high frequency power makes it larger value at shorter time than a step-shaped increase of a high frequency power, thereby improving a film forming rate. As shown by reference character (c) in FIG. 16, even though in the middle of continuously increasing a high frequency power in a rate of 67 W/min, a high frequency power is increased in a rate of 172 W/min from 180 seconds to 267 seconds, there is no problem. If a high frequency power increases continuously, the film density of a film formed during such period also continuously increases.

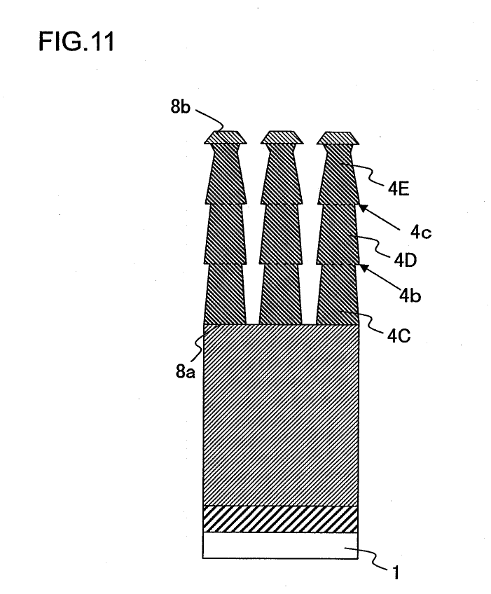

FIG. 11 is a schematic cross-sectional view when the hard mask 4 in FIG. 5 is formed so as to have three film densities. Reference numeral 4C indicates a hard mask formed with an AC film having a film density of 1.25 g/cm³ or more, reference numeral 4D indicates a hard mask having a larger film density than the hard mask 4C, and reference numeral 4E indicates a hard mask having a larger film density than the hard mask 4D. Also, reference numeral 4b indicates a step between the hard masks 4C and 4D, and reference numeral 4c indicates a step between the hard masks 4D and 4E.

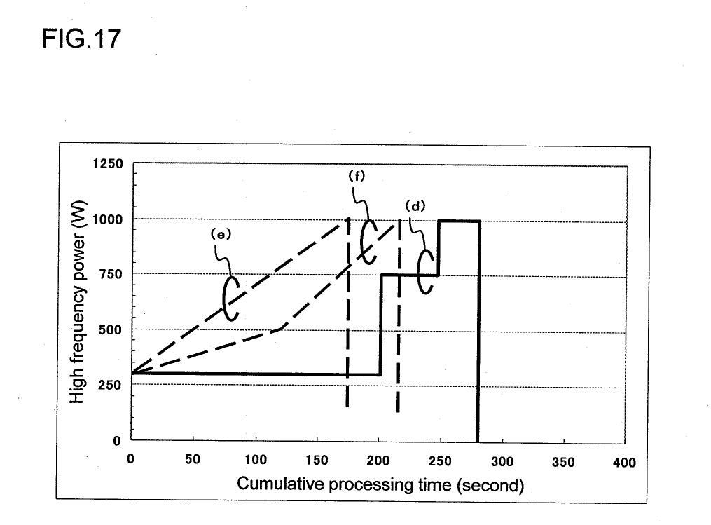

FIG. 17 is one timing chart showing the switch of high frequency power at the time of forming the hard masks 4C to 4E shown in FIG. 11. The hard mask 4C having the film density of 1.25 g/cm³ is formed by the high frequency power of 300 W, the hard mask 4D having the film density of 1.38 g/cm³ is formed by the high frequency power of 750 W, and hard mask 4E having the film density of 1.42 g/cm³ is formed by the high frequency power of 1000 W. Each hard mask has a thickness of 233.3 nm and a total thickness of the hard mask is 700 nm as the thickness in FIG. 2. Herein, as shown by reference character (d) in FIG. 17, the hard mask 4C positioned in the lower portion of the hard mask 4 is formed by a high frequency power of 300 W, and after 201 seconds from finishing forming the hard mask 4C, the high frequency power is increased up to 750 W in a step shape to form the hard mask 4D. After 247 seconds from finishing forming the hard mask 4D, the high frequency power is increased up to 1000 W in a step shape to form the hard mask 4E, and after 280 seconds, a high frequency power is reduced down to 0 W to finish the process for forming the hard masks.

As in FIG. 16, the method for applying the high frequency power is not limited to the method which increases it in a step shape depending on the film densities, and as shown by reference character (e) in FIG. 17, may continuously increase in a rate of 243 W/min from 0 to 173 seconds. If a high frequency power continuously increases, it is possible to achieve the same effect as shown in FIG. 16, i.e., shortening a cumulative processing time. As shown by reference character (f) in FIG. 17, even though in the middle of continuously increasing a high frequency power in a rate of 100 W/min, a high frequency power is increased in a rate of 314 W/min from 120 seconds to 215 seconds, there is no problem. If a high frequency power increases continuously, the film density of a film formed during such period also continuously increases, as in FIG. 16.

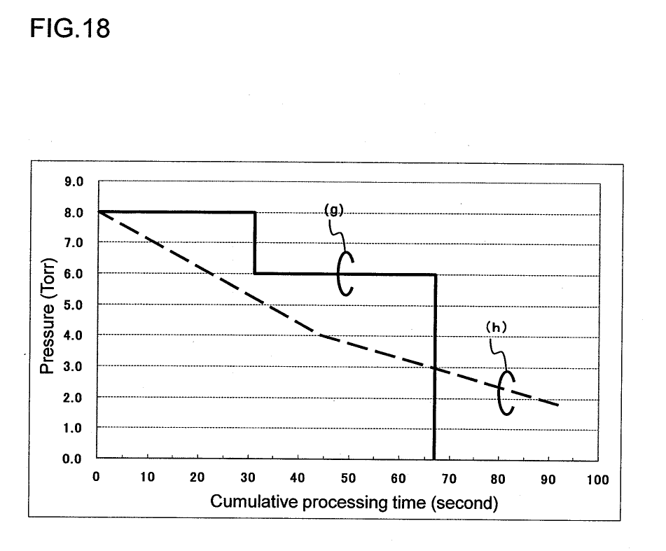

FIG. 18 is one timing chart showing the switch of pressure in a chamber when a hard mask 4 having two different film densities is formed by changing a pressure in a chamber of a film forming apparatus. Each hard mask has a thickness of 350 nm and a total thickness of the hard mask is 700 nm. Herein, as shown by reference character (g) in FIG. 18, first, a film having a small film density is formed at a pressure of 8.0 Torr, after 31 seconds, a film having a large film density is formed by reducing the pressure down to 6.0 Torr in a step shape, and after 67 seconds, the film formation is finished by changing the flow rate of material gas to 0 sccm. Herein, the method for applying the pressure is not limited to the method which reduces it in a step shape. As shown by reference character (h) in FIG. 18, even though in the middle of continuously reducing pressure in a rate of 5.3 Torr/min, a reduction rate of pressure reduces down to 2.8 Torr/min from 45 seconds to 132 seconds, there is no problem. If pressure reduces continuously, the film density of a film formed during such period also continuously increases.

This exemplary embodiment explains one method for forming a contact plug, but may be applied to the formation of hole having a large aspect ratio, other than the contact plug. For example, a capacitor hole can be formed as a second pattern in a base film, using the method according to the present invention and a lower electrode of a capacitor can be formed in the capacitor hole.

### Second Exemplary Embodiment

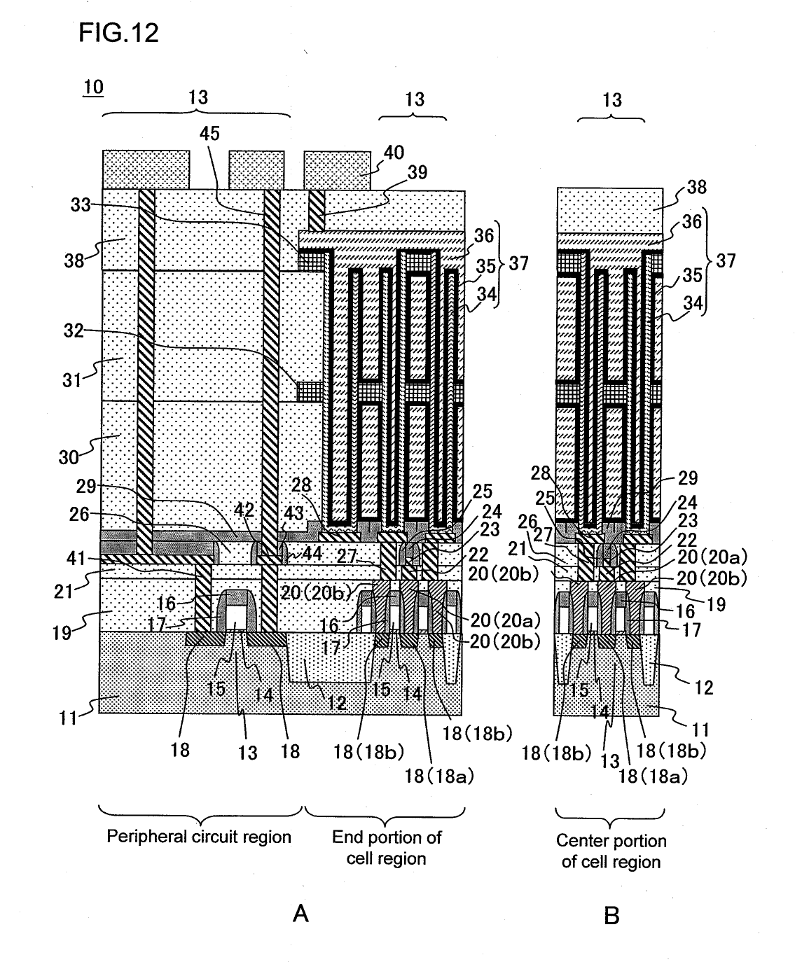

FIG. 12 shows a schematic cross-sectional view illustrating the structure of a DRAM (Dynamic Random Access Memory) 10 according to the second exemplary embodiment. FIG. 12A shows a peripheral circuit region and an end portion of a cell region end, and FIG. 12B shows a center portion of a cell region. The end portion and center portion are referred to as a cell region.

In the cell and peripheral circuit regions of the DRAM 10 according to this exemplary embodiment, a planar type MIS transistor is provided in a semiconductor substrate 11 (hereinafter, referred to as “silicon substrate 11”). The planar type MIS transistor is disposed in an active region 13 surrounded by an STI (Shallow Trench Isolation) 12, which is an isolation region formed in the silicon substrate. The planar type MIS transistor comprises a gate insulating film 14 provided on the surface of the silicon substrate 11, a gate electrode 15 covering the gate insulting film 14, and diffusion layers 18 which are provided around the lower portion of the gate insulating film 14 and is source and drain. The upper portion and side portion of the gate electrode 15 are covered with an insulating film 16 and a sidewall insulating film 17. The diffusion layers 18 are disposed in the silicon substrate 11 in which the gate insulating film 14 is not formed thereon, and is not disposed in a region just below the gate insulating film 14.

In order to more simply explain the constitution, two MIS transistors are provided in the active region 13 in FIG. 12B, but thousands of to hundreds of thousands of MIS transistors are actually provided. The diffusion layers 18 are disposed in the upper portion of the silicon substrate 11 covered by a first interlayer insulating film 19 and is configured so as to have conductivity opposite to the impurity contained in the silicon substrate 11.

In the cell region shown in FIGS. 12A and 12B, first plugs 20 connected to the diffusion layers 18 are configured so as to penetrate through the first interlayer insulating film 19, so that it is disposed between sidewall insulating films 17 of the adjacent planar type transistors. Herein, a first contact plug 20a contacting with a diffusion layer 18a is connected to a second contact plug 22 configured so as to penetrate through a second interlayer insulating film 21, and a first contact plug 20b contacting with a diffusion layer 18b is connected to a third contact plug 27 configured to penetrate the second interlayer insulating film 21 and a third interlayer insulating film 26.

Also, a first wiring 23 to be a bit line is disposed on the second interlayer insulating film 21 which is covered with an insulating film 24 and a sidewall insulating film 25, and connected to the second plug 22. In order to secure an alignment margin between a capacitor 37, which will be described later, and the third contact plug 27, a contact pad 28 is provided on the third interlayer insulating film 26. The contact pad 28 is connected to the third contact plug 27.

On the contact pad 28, the capacitor 37 comprising a lower electrode 34, a capacity film 35, and an upper electrode 36 is configured so as to penetrate through a cover film 29 for protecting a fourth interlayer insulating film 30, a fifth interlayer insulating film 31 and the third interlayer insulating film 26. The lower electrode 34 of the capacitor 37 is connected to contact pad 28. Also, the side surface of the capacitor 37 contacts with first and second beams 32, 33 for preventing the capacitor from collapsing. Adjacent capacitors 37 are supported with each other via the first and second beams 32, 33. On the capacitor 37, a fourth contact plug 39 connected to the upper electrode 36 is provided in a sixth interlayer insulating film 38 covering the upper electrode 36. The fourth contact plug 39 is connected to a second wiring 40 disposed on the sixth interlayer insulating film 38.

In the peripheral circuit region shown in FIG. 12 A, a fifth contact plug 41 connected to the diffusion layer 18 is configured so as to penetrate the first interlayer insulating film 19 and the second interlayer insulating film 21. Also, on the second interlayer insulating film 21, a third wiring 42 is disposed so as to being covered with an insulating film 43 and a sidewall insulating film 44. The third wiring 42 is connected to the fifth contact plug 41. The cover film 29 covers the third wiring 42. On the cover film 29, the fourth interlayer insulating film 30, the fifth interlayer insulating film 31, and the sixth interlayer insulating film 38 are provided, and a sixth contact plug 45 is configured so as to penetrate through each of the fourth to sixth interlayer insulating films and is connected to the second wiring 40.

In a DRAM including the aforementioned structure, a manufacturing method according to this exemplary embodiment is used to form a hole to be mold for forming the second to six contact plugs and the capacitor. Particularly, the method is suitable for forming a long hole such as a mold for the sixth contact plug or capacitor.

As mentioned above, in the method for manufacturing a semiconductor device according to the present invention, a high frequency power increases or a flow rate of hydrocarbon gas which is a material of an AC film reduces in chemical vapor deposition (plasma CVD) in the middle of forming a hard mask made of AC film. As described above, it is possible to make the film density in the lower portion of a hard mask become smaller than the film density in the upper portion of the hard mask by changing the forming conditions of the hard mask made of AC film in the middle of forming it. As a result, since the side etching amount in the upper portion of the hard mask reduces and the upper portion of the hard mask is protruded to prevent the lower portion of the hard mask from being etched, resulting in inhibiting the reduction of the film in the lower portion of the hard mask and reducing the ununiformity of dimension in the hard mask.

As described above, the preferred exemplary embodiments of the present invention were explained, but the present invention is not limited to the above exemplary embodiments. Various modification of the present invention may be made in a range not departing from the summary of the present invention, and this modified exemplary embodiment is included in the scope of the present invention.

Also, the term “step shape” used in the specification, drawings, and claims means a discontinuous change in like a step. The term “surface of hard mask” used in the specification, drawings, and claims means a surface that is disposed in opposite side of a face of the hard mask adjacent to a base film in a thickness direction and faces the face of the hard mask adjacent to the base film. For example, the surface of a hard mask is indicated by reference numeral 8b in FIGS. 2 and 11.

It is apparent that the present invention is not limited to the above embodiments, but may be modified and changed without departing from the scope and spirit of the invention.

1. A method for manufacturing a semiconductor device, comprising:
forming a base film on a semiconductor substrate;
forming an amorphous carbon film on the base film so that a face of the amorphous carbon film adjacent to the base film has a smaller film density than a film density of a surface of the amorphous carbon film;
forming a first pattern in the amorphous carbon film; and
etching the base film using the amorphous carbon film including the first pattern as a mask to form a second pattern in the base film.

2. The method for manufacturing a semiconductor device according to claim 1,
wherein in forming the amorphous carbon film, the film density of the amorphous carbon film reduces from the surface of the amorphous carbon film to the face of the amorphous carbon film adjacent to the base film.

3. The method for manufacturing a semiconductor device according to claim 1,
wherein in forming the amorphous carbon film, the amorphous carbon film is formed by plasma CVD using a high frequency plasma generated by applying a high frequency power to process gas while a reaction chamber into which the process gas is introduced is maintained under pressure of an atmospheric pressure or less, and
the process gas contains at least hydrocarbon gas.

4. The method for manufacturing a semiconductor device according to claim 3,
wherein the high frequency power in the plasma CVD increases in a step shape with processing time.

5. The method for manufacturing a semiconductor device according to claim 3,
wherein the high frequency power in the plasma CVD continuously increases with processing time.

6. The method for manufacturing a semiconductor device according to claim 3,
wherein the pressure in the reaction chamber reduces in a step shape with processing time.

7. The method for manufacturing a semiconductor device according to claim 3,
wherein the pressure in the reaction chamber continuously reduces with processing time.

8. The method for manufacturing a semiconductor device according to claim 1,
wherein the film density of the amorphous carbon film is in a range from 1.2 g/cm³ to 2.0 g/cm³.

9. The method for manufacturing a semiconductor device according to claim 1, after etching the base film, further comprising:
removing the amorphous carbon film including the first pattern; and
covering an inner wall of the second pattern with conductive material.

10. The method for manufacturing a semiconductor device according to claim 9,
wherein the second pattern is a hole,
a contact plug is formed in the hole by covering the inner wall of the second pattern with the conductive material, and
a wiring is further formed on the contact plug.

11. The method for manufacturing a semiconductor device according to claim 9,
wherein the second pattern is a hole, and
at least a lower electrode of a capacitor is formed in the hole by covering the inner wall of the second pattern with the conductive material.

12. The method for manufacturing a semiconductor device according to claim 10,
wherein at least the wiring is electrically connected to an MIS transistor formed in the semiconductor substrate.

13. The method for manufacturing a semiconductor device according to claim 11,
wherein at least the lower electrode of the capacitor is electrically connected to an MIS transistor formed in the semiconductor substrate.

14. A method for forming a hard mask, comprising:
forming a hard mask comprising an amorphous carbon film on a base film so that a face of the amorphous carbon film adjacent to the base film has a smaller film density than a film density of a surface of the amorphous carbon film; and
forming a pattern of the hard mask.

15. The method for forming a hard mask according to claim 14,
wherein in forming the hard mask, the film density of the amorphous carbon film reduces from the surface of the amorphous carbon film to the face of the amorphous carbon film adjacent to the base film.

16. The method for forming a hard mask according to claim 14,
wherein in forming the hard mask, the amorphous carbon film is formed by plasma CVD using a high frequency plasma generated by applying a high frequency power to process gas while a reaction chamber into which the process gas is introduced is maintained under pressure of an atmospheric pressure or less, and
the process gas contains at least hydrocarbon gas.

17. The method for forming a hard mask according to claim 16,
wherein the high frequency power in the plasma CVD increases in a step shape with processing time.

18. The method for forming a hard mask according to claim 16,
wherein the high frequency power in the plasma CVD continuously increases with processing time.

19. The method for forming a hard mask according to claim 16,
wherein the pressure in the reaction chamber reduces in a step shape with processing time.

20. The method for forming a hard mask according to claim 16,
wherein the pressure in the reaction chamber continuously reduces with processing time.
